(19) United States
(12) Patent Application Publication
(10) Pub. No.: US 2014/0342501 A1
(43) Pub. Date: Nov. 20, 2014

(54) PACKAGE STACKS AND METHODS OF MANUFACTURING THE SAME

(71) Applicant: SAMSUNG ELECTRONIS CO., LTD., Gyeonggi-do (KR)

(72) Inventor: Il-Ho KIM, Nowon-gu (KR)

(21) Appl. No.: 14/448,377

(22) Filed: Jul. 31, 2014

Related U.S. Application Data
(62) Division of application No. 13/541,299, filed on Jul. 3, 2012.

(30) Foreign Application Priority Data
Aug. 26, 2011 (KR) 10-2011-0085763

(51) Int. Cl. H01L 25/00; H01L 21/78; H01L 21/56; H01L 23/00

(52) U.S. Cl. CPC H01L 25/50; H01L 24/81; H01L 21/78; H01L 21/561; H01L 23/562; H01L 2224/16227; H01L 2224/16145; H01L 2224/48091; H01L 2224/48227; H01L 2225/06513; H01L 2225/06517
USPC 438/107

(57) ABSTRACT

A package stack includes a first package, a second package, first solder balls and a molding member. The first package includes a first package substrate, a first semiconductor chip on the first package substrate and connecting pads. The second package includes a second package substrate and a second semiconductor chip on the second package substrate. The second package is disposed over the first package. The first solder balls are in contact with the connecting pads and a bottom of a peripheral portion of the second package substrate. The molding member covers an upper surface of the second package substrate and the second semiconductor chip. A portion of the molding member overlapping the first solder balls has a thickness smaller than a thickness of another portion of the molding member.

### CROSS-REFERENCE TO RELATED APPLICATIONS

This application is a Divisional of U.S. Ser. No. 13/541,299 filed on Jul. 3, 2012, which claims priority under 35 USC §119 to Korean Patent Application No. 2011-0085763, filed on Aug. 26, 2011 in the Korean Intellectual Property Office (KIPO), the entire disclosure of which is incorporated by reference herein.

### TECHNICAL FIELD

Exemplary embodiments relate to package stacks and methods of manufacturing the same. More particularly, exemplary embodiments relate to package stacks including a plurality of semiconductor chips and methods of manufacturing the same.

### DISCUSSION OF THE RELATED ART

A semiconductor chip may be formed on a semiconductor substrate by various processes. A plurality of semiconductor chips may be packaged in a semiconductor package. To improve storage capacity of the semiconductor package, the semiconductor chips may be stacked.

### SUMMARY

Exemplary embodiments provide package stacks that can reduce damage to solder balls to provide high reliability and methods of manufacturing the package stacks.

According to an exemplary embodiment, there is provided a package stack. The package stack includes a first package, a second package, first solder balls and a molding member. The first package includes a first package substrate, a first semiconductor chip on the first package substrate and connecting pads. The second package includes a second package substrate and a second semiconductor chip on the second package substrate. The second package is disposed over the first package. The first solder balls contact the connecting pads and a bottom of a peripheral portion of the second package substrate. The molding member covers an upper surface of the second package substrate and the second semiconductor chip. A portion of the molding member overlapping the first solder balls has a thickness smaller than a thickness of another portion of the molding member.

In an exemplary embodiment, the connecting pads may be spaced apart from the first semiconductor chip in a lateral direction.

In an exemplary embodiment, the first solder balls are arranged on peripheral portions of the first and second package substrate.

In an exemplary embodiment, the molding member may include a first portion having a first thickness and a second portion having a second thickness smaller than the first thickness, The first portion may cover the second semiconductor chip and the first portion may be disposed over the second solder balls.

In an exemplary embodiment, a thickness of the second portion may gradually decrease toward an edge portion of the molding member.

In an exemplary embodiment, the second portion may have a slope shape or an inclined shape.

In an exemplary embodiment, the second portion may include a plurality of stepped portions.

in an exemplary embodiment, second solder balls may be arranged on a lower surface of the first package substrate. The second solder balls may include an external connecting terminal.

According to an exemplary embodiment, there is provided a method of manufacturing a package stack. In the method, a first package including a first semiconductor chip and connecting pads is formed. A second package including a second package substrate, a second semiconductor chip on the second package substrate and solder balls on a bottom of the second package substrate is formed. A molding member covering an upper surface of the second package substrate and the second semiconductor chip is formed. A portion of the molding member overlapping the solder balls has a thickness smaller than a thickness of another portion of the molding member. The solder balls are connected to the connecting pads such that the second semiconductor chip is electrically connected to the first semiconductor chip.

In an exemplary embodiment, the solder balls may be formed on a bottom of a peripheral portion the second package substrate.

In an exemplary embodiment, in the formation of the molding member, a preliminary molding member covering the second semiconductor chip may be formed on the second package substrate. A portion of the preliminary molding member overlapping the solder balls may be removed.

In an exemplary embodiment, in the formation of the molding member, a mold forming member may be arranged over the second package. The mold forming member may include a protrusion disposed over the solder balls. A mold material may be injected through a gap between the mold forming member and the second package substrate to form the molding member. The mold forming member may be removed.

in an exemplary embodiment, the portion of the preliminary molding member may be removed by a first sawing process utilizing a blade.

In an exemplary embodiment, a second sawing process may divide the second package substrate into a plurality of portions.

In an exemplary embodiment, the process for removing the portion of the preliminary molding member and the second sawing process may be performed in a single sawing process utilizing two blades.

According to the exemplary embodiments, a peripheral portion of a molding member located on an upper package may have a relatively thin thickness. A portion of the molding member substantially facing conductive balls for connecting upper and lower semiconductor chips to each other may have a relatively thin thickness. Accordingly, the peripheral portion of the molding member may have flexibility greater than flexibility of other portions. Thus, a thermal stress exerted to the conductive balls may be reduced so that defects of the conductive balls, for example, cracks, seams, or voids can be prevented. Therefore, a package stack having great reliability may be obtained.

### BRIEF DESCRIPTION OF THE DRAWINGS

Exemplary embodiments will be more clearly understood from the following detailed description taken in conjunction with the accompanying drawings, wherein:

FIG. 1 is a cross-sectional view illustrating a package stack in accordance with an exemplary embodiment;

FIG. 2 is a cross-sectional view illustrating a package stack in accordance with an exemplary embodiment;

FIGS. 3 to 5 are cross-sectional views illustrating package stacks in accordance with some exemplary embodiments;

FIGS. 6 to 15 are cross-sectional views illustrating a method of manufacturing the package stack of FIG. 1 in accordance with an exemplary embodiment;

FIG. 16 is a cross-sectional view illustrating a method of manufacturing the package stack of FIG. 1 in accordance with an exemplary embodiment;

FIGS. 17 and 18 are cross-sectional views illustrating a method of manufacturing the package stack of FIG. 1 in accordance with an exemplary embodiment; and

FIG. 19 is a block diagram illustrating an electronic device including a package stack in accordance with an exemplary embodiment.

### DESCRIPTION OF EMBODIMENTS

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein.

It will be understood that when an element or layer is referred to as being “on,” “connected to” or “coupled to” another element or layer, it can be directly on, connected or coupled to the other element or layer or intervening elements or layers may be present. Like numerals may refer to like or similar elements throughout the drawings and the specification.

As used herein, the singular forms “a,” “an” and “the” are intended to include the plural forms as well, unless the context clearly indicates otherwise.

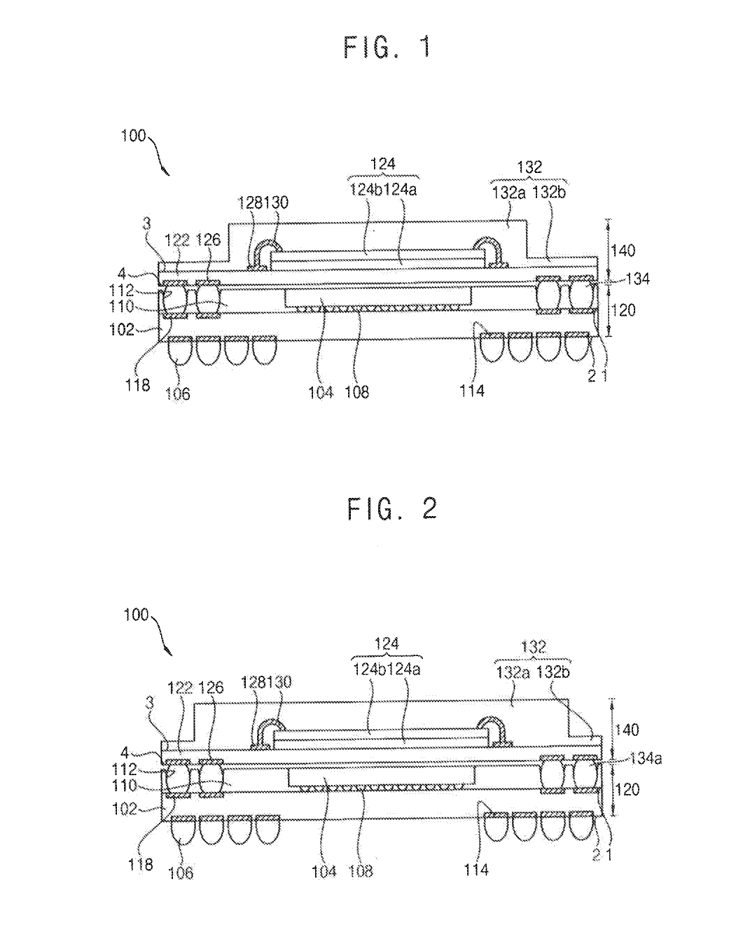

FIG. 1 is a cross-sectional view illustrating a package stack in accordance with an exemplary embodiment. FIG. 2 is a cross-sectional view illustrating a package stack in accordance with an exemplary embodiment.

Referring to FIGS. 1 and 2, a package stack 100 includes a first package 120 and a second package 140 stacked on the first package 120.

The first package 120 includes a first package substrate 102, a first semiconductor chip 104, conductive members 106 and 108, and a first molding member 110. The first package 120 corresponds to a lower package of the package stack 100. For example, according to an embodiment, the first package 120 includes LSI logic chips for controlling memory devices of an upper package.

A plurality of micro bumps 108 are disposed on a first surface 1 of the first package substrate 102. The micro bumps 108 include a plurality of conductive balls. The first semiconductor chip 104 is electrically connected to the first package substrate 102 via the micro bumps 108. According to an embodiment, electrodes (not illustrated) are respectively disposed on bottoms of the micro bumps 108.

First pads 118 are electrically connected to a second semiconductor chip 124 and are disposed on the first surface 1 of the first package substrate 102. The first pads 118 are spaced apart from the first semiconductor chip 104 in a lateral direction and are arranged to surround a lateral portion of the first semiconductor chip 104. The first pads 118 include a metal. Electrical signals are transmitted via the first pads 118.

A first molding member 110 is disposed on the first surface 1 of the first package substrate 102. The first molding member 110 includes an epoxy molding compound (EMC). The first molding member 110 does not cover the first pads 118. For example, according to an embodiment, the first molding member 110 includes a plurality of openings 112 which respectively expose the first pads 118.

The first molding member 110 has a planar or leveled upper surface. For example, according to an embodiment, a top surface of the first semiconductor chip 104 is exposed by the first molding member 110. Alternatively, the first molding member 110 covers the first semiconductor chip 104.

Second pads 114 are disposed on a second surface 2 of the first package substrate 102. The second surface 2 is positioned opposite or substantially opposite to the first surface 1. First solder balls 106 are in contact with the second pads 114. The first solder balls 106 function as external connecting terminals.

The second package 140 is stacked or mounted on the first package 120. In an exemplary embodiment, the second package 140 includes a second package substrate 122, the second semiconductor chip 124, conductive wires 130 and a second molding member 132.

At least one second semiconductor chip 124 is disposed on a third surface 3 of the second package substrate 122. According to an embodiment, a plurality of bonding pads (not illustrated) are disposed on the second semiconductor chip 124. The second semiconductor chips 124 include memory chips.

Third pads 128 are disposed on the third surface 3 of the second semiconductor substrate 122. The third pads 128 are spaced apart from the second semiconductor chip 124 in a lateral direction and are arranged to surround a lateral portion of the second semiconductor chip 124. The bonding pads of the second semiconductor chip 124 are electrically connected to the third pads 128 via the conductive wires 130.

Fourth pads 126 are disposed on a fourth surface 4 of the second package substrate 122. The fourth surface 4 is positioned opposite or substantially opposite to the third surface 3. The fourth pads 126 face or substantially face a peripheral portion of the third surface 3 spaced apart from the second semiconductor chip 124.

Second solder balls 134 electrically connect the first and fourth pads 118 and 126 with each other. The second solder balls 134 are spaced apart from the lateral portions of the first and second semiconductor chips 104 and 124. For example, according to an embodiment, the second solder balls 134 are located on the peripheral portions of the first and second package substrate 102 and 122.

The second molding member 132 covers the third surface 3 of the second package substrate 122 and the second semiconductor chip 124. For example, according to an embodiment, the second molding member 132 includes an EMC.

In an exemplary embodiment, the second molding member 132 includes a first portion 132a covering or substantially covering the second semiconductor chip 124 and a second portion 132b except for the first portion 132a. The second portion 132b covers the peripheral portion of the second package substrate 122. The first portion 132a has a first thickness, and the second portion 132b has a second thickness smaller or substantially smaller than the first thickness. In an exemplary embodiment, the second portion 132b is disposed over the second solder balls 134 that are disposed on the peripheral portions of the first and second package substrate 102 and 122.

The portion of the second molding member 132 disposed over the second solder balls 134 has the second thickness. The second thickness is sufficiently small to prevent a defect, such as cracks, from being generated in the second solder balls 134 due to a thermal stress of the second molding member 132. The second thickness is sufficiently large to protect circuits formed on the second package substrate 122.

In an exemplary embodiment, as illustrated in FIG. 2, the second portion 132b is disposed over an outermost second solder ball 134a. The second portion 132b disposed over the outermost second solder ball 134a where the most thermal stress is exerted has a relatively thin thickness.

The first and second packages 120 and 140 are connected to each other via the second solder balls 134. The first and second packages 120 and 140 have different thermal expansion coefficients from each other. Thus, the first and second packages 120 and 140 expand or shrink to different degrees according to an inner or outer temperature of the package stack 100. The first and second packages 120 and 140 are repeatedly expanded or shrunken by high heat or thermal energy generated in the first and second semiconductor chips 104 and 124 during an operation of the package stack 100. Thus, the second solder balls 134 electrically connecting the first and second packages 120 and 140 with each other are continuously exposed to the thermal stress, and defects, such as cracks or seams, may be thus caused in the second solder balls 134. As a size of the second solder ball 134 decreases, the second solder ball 134 becomes more vulnerable to the thermal stress. The cracks may change electrical properties of the second solder ball 134 and may reduce reliability of the package stack 100.

Peripheral portions of the first and second packages 120 and 140 may be thermally transformed more easily than central portions of the first and second packages 120 and 140. Thus, the outermost solder ball 134a among the second solder balls 134 may undergo the highest degree of thermal stress.

According to an exemplary embodiment, the portion of the second molding member 132 disposed or substantially disposed over the second solder balls 134 has a thickness smaller than a thickness of other portions of the second molding member 132. Thus, the peripheral portion of the second package 140 has relatively large flexibility to reduce the thermal stress. Therefore, the cracks or the seams generated in the second solder balls 134 are reduced and thus reliability of the package stack 100 is increased.

According to an exemplary embodiment, a package-on-package (POP) type package stack includes the first and second packages 120 and 140. However, alternatively, a semiconductor package including only the second package 140 is provided as the package stack.

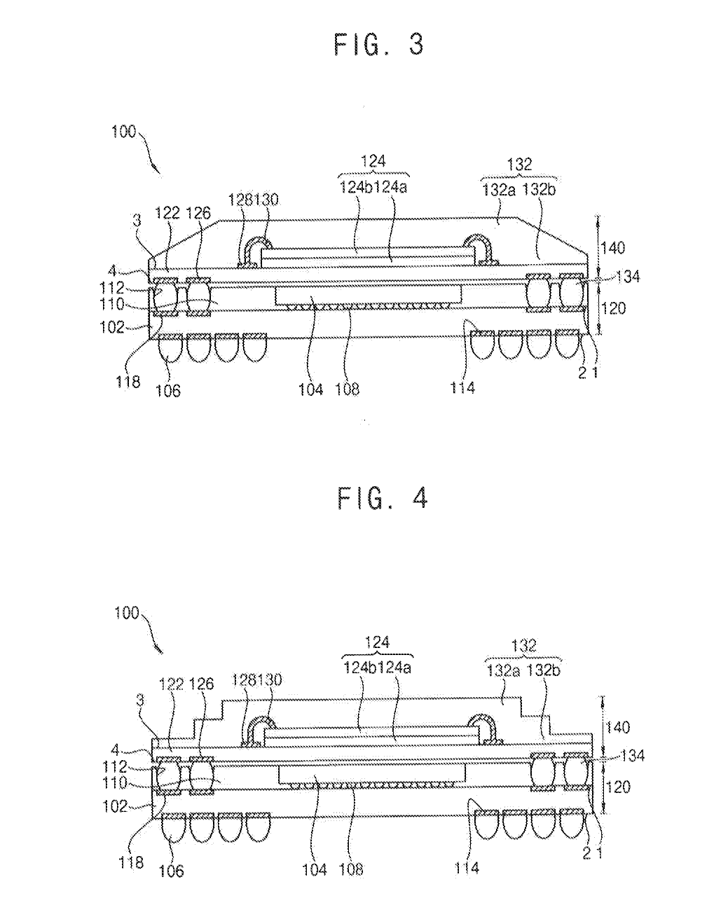

FIGS. 3 to 5 are cross-sectional views illustrating package stacks in accordance with some exemplary embodiments.

The package stacks illustrated in FIGS. 3 and 4 may have constructions the same or substantially the same as the package stack of FIG. 1 except for shapes of the second molding members.

Referring to FIG. 3, a second molding member 132 includes a first portion 132a having a first thickness and a second portion 132b having a second thickness smaller than the first thickness. The first portion 132a covers or substantially covers the second semiconductor chip 124, and the second portion 132b is disposed on the peripheral portion of the second package substrate 122. A thickness of the second portion 132b is gradually reduced from a central portion to a peripheral portion of the second molding member 132. For example, according to an embodiment, the second portion 132b has a slope shape or an inclined shape.

Referring to FIG. 4, the second portion 132b has a plurality of stepped portions. A thickness of the second portion 132b is reduced from the central portion to the peripheral portion of the second molding member 132.

The upper package according to an exemplary embodiment is stacked or mounted on various types of lower packages.

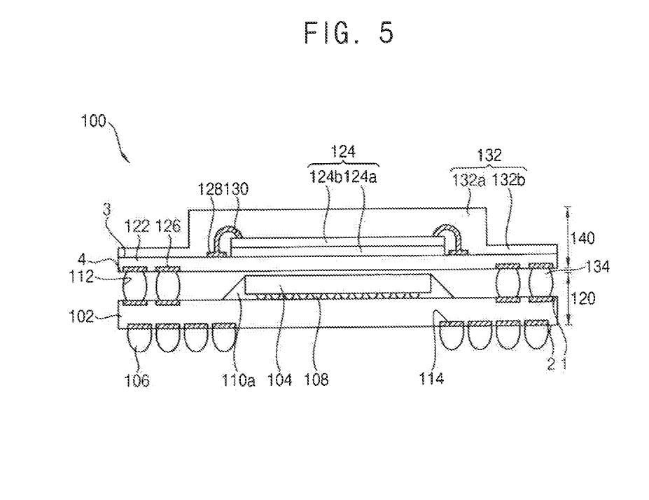

Referring to FIG. 5, a first molding member 110a of a lower package (a first package) 120 has an under-fill structure filling a space under the first semiconductor chip 104.

in an exemplary embodiment, the first molding member of the lower package has the under-fill structure, and the upper packages as illustrated in FIGS. 2 to 4 is mounted on the lower package.

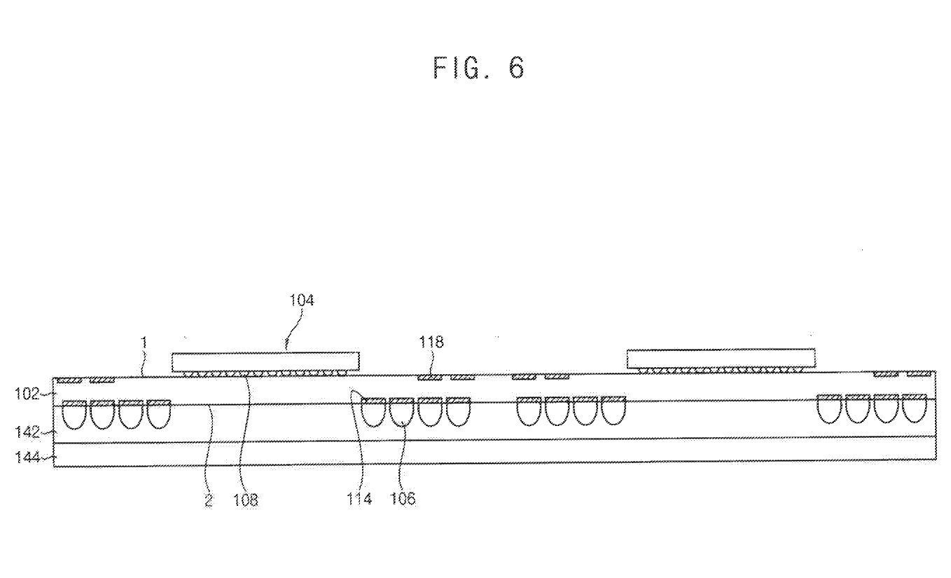

FIGS. 6 to 15 are cross-sectional views illustrating a method of manufacturing the package stack of FIG. 1 in accordance with an exemplary embodiment.

Referring to FIG. 6, first pads 118 are formed on a first surface 1 of a first package substrate 102. Second pads 114 are formed on a second surface 2 of the first package substrate 102.

First solder balls 106 are formed on the second pads 114. A first temporary adhesive 142 is coated on the second surface 2 and the first solder halls 106. A first carrier substrate 144 is attached to the first temporary adhesive 142. The first carrier substrate 144 and the first temporary adhesive 142 protect the first solder balls 106.

Micro bumps 108 including conductive balls are formed on the first surface 1 of the first package substrate 102. The micro bumps 108 are arranged on portions of the first package substrate 102 and are surrounded by the first pads 118.

A first semiconductor chip 104 is placed on the micro bumps 108. A reflow process is performed to attach the first semiconductor chip 104 to the first package substrate 102 via the micro bumps 108. Accordingly, the first semiconductor chip 104 is electrically connected to the first package substrate 102.

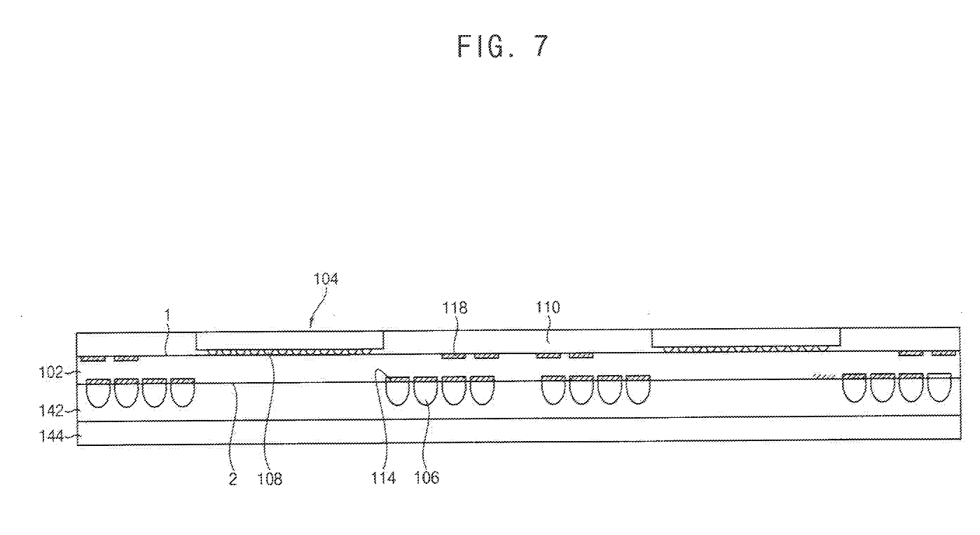

Referring to FIG. 7, a first molding member 110 is formed on the first surface 1 of the first package substrate 102. The first molding member 110 fills at least a gap between the first semiconductor chip 104 and the first package substrate 102.

In an exemplary embodiment, the first molding member 110 exposes top surfaces of the first semiconductor chips 104. The first molding member 110 fills a gap between the adjacent first semiconductor chips 104 and the gap between the first semiconductor chip 104 and the first package substrate 102.

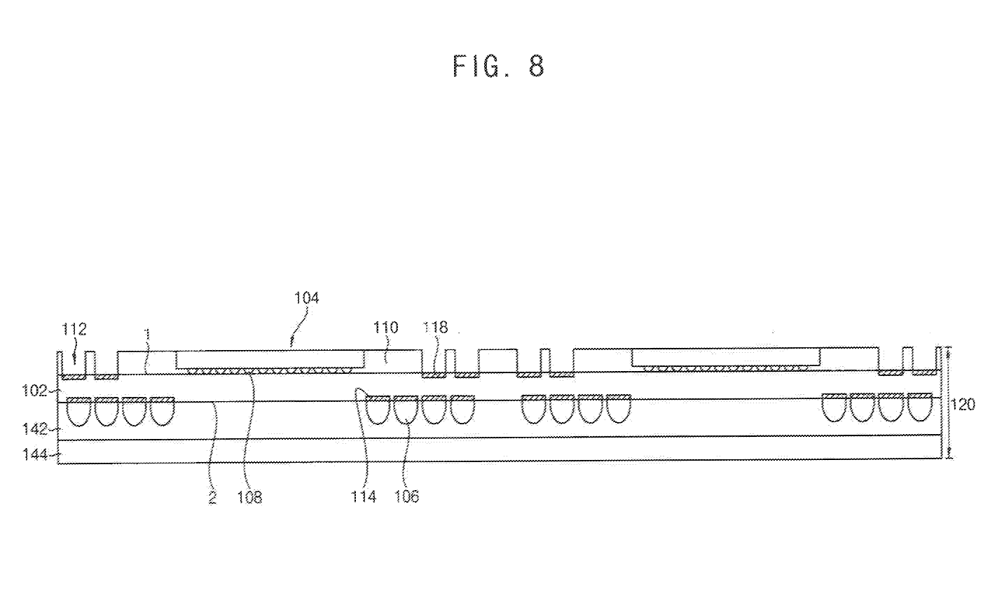

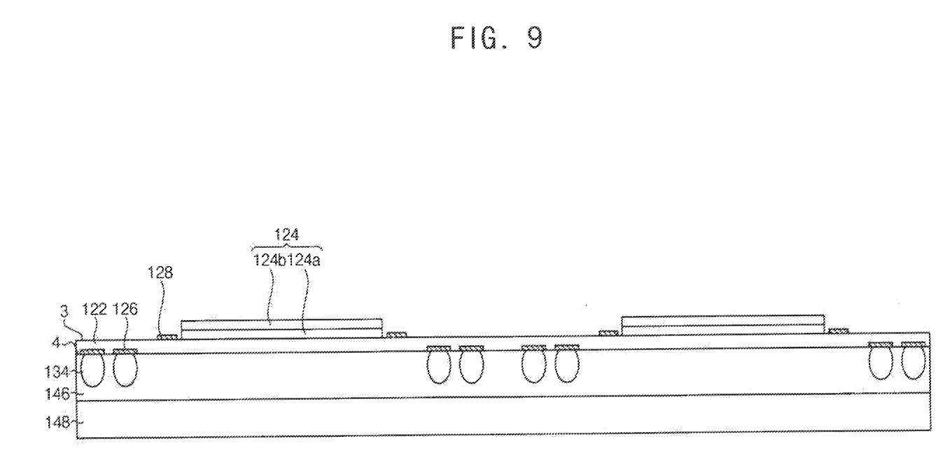

Referring to FIG. 8, the first molding member 110 is partially removed to form openings 112 exposing the first pads 118. The openings 112 are formed using a laser.

In the case that the first molding member 110 has an under-fill structure, the opening 112 may not be formed.

The first package substrate 102 is divided, e.g., into two portions, by a sawing process, thus forming first packages 120 each including the first semiconductor chip.

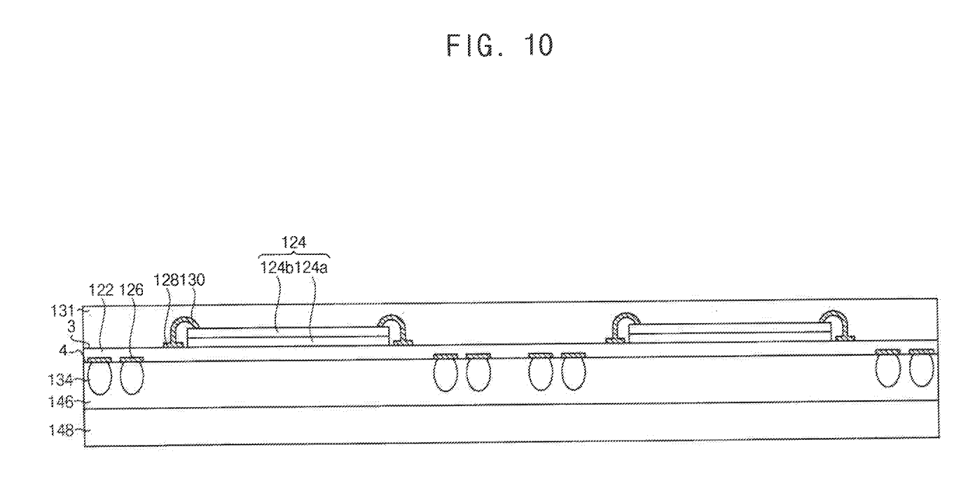

Referring to FIG. 9, third pads 128 are formed on a third surface 3 of a second package substrate 122. Fourth pads 126 are formed on a fourth surface 4 of the second package substrate 122.

Second solder balls 134 are formed to contact the fourth pads 126. The second solder balls 134 are arranged to he spaced apart from a second semiconductor chip 124 in a lateral direction. The second solder balls 134 are in contact with the first pads 118 by a subsequent process.

A second temporary adhesive 146 is coated on the fourth surface 4 of the second package substrate 122 and covers the second solder balls 134, and a second carrier substrate 148 is attached to the second temporary adhesive 146. The second carrier substrate 148 protects the second solder balls 134.

The second semiconductor chip 124 is arranged on the third surface 3 of the second package substrate 122. The second semiconductor chip 124 is attached to the second package substrate 122, for example, by an adhesive (not illustrated). The second semiconductor chip 124 has a single layer structure or a multi-layer structure. A lateral portion of the second semiconductor chip 124 is surrounded by the second solder balls 134.

Referring to FIG. 10, bonding pads (not illustrated) of the second semiconductor chip 124 are electrically connected to the third pads 128 through bonding wires 130.

A preliminary second molding member 131 is formed to cover the third surface 3 of the second package. substrate 122, the second semiconductor chip 124 and the conductive wires 130.

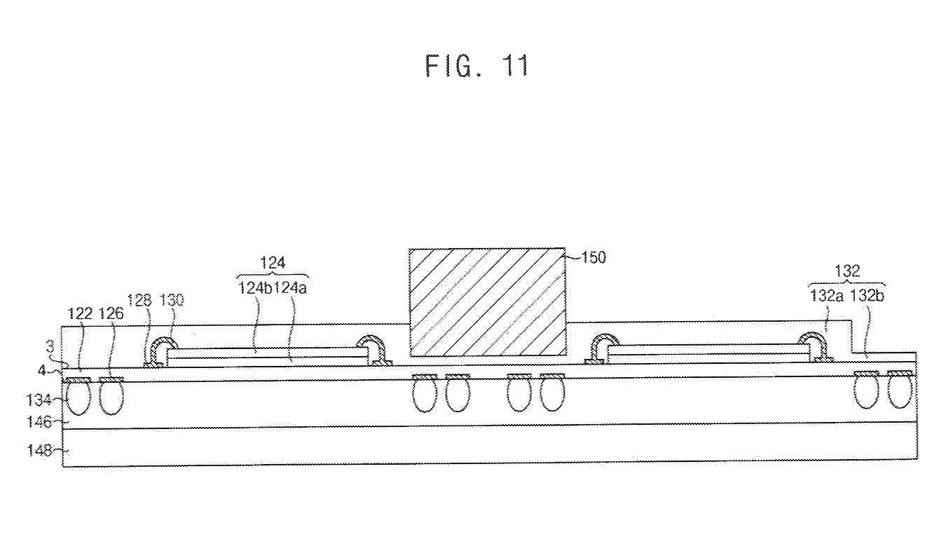

Referring to FIG. 11, a portion of the preliminary second molding member 131 overlapping or substantially overlapping or facing the second solder balls 134 is removed to form a second molding member 132. The second molding member 132 includes a first portion 132a covering or substantially covering the second semiconductor chip 124 and a second portion 132b except for the first portion 132a. In an exemplary embodiment, the first portion 132a has a first thickness, and the second portion 132b has a second thickness smaller than the first thickness. The second solder balls 134 are located under the second portion 132b.

In an exemplary embodiment, the preliminary second molding member 131 is partially removed by a first sawing process using a first blade 150.

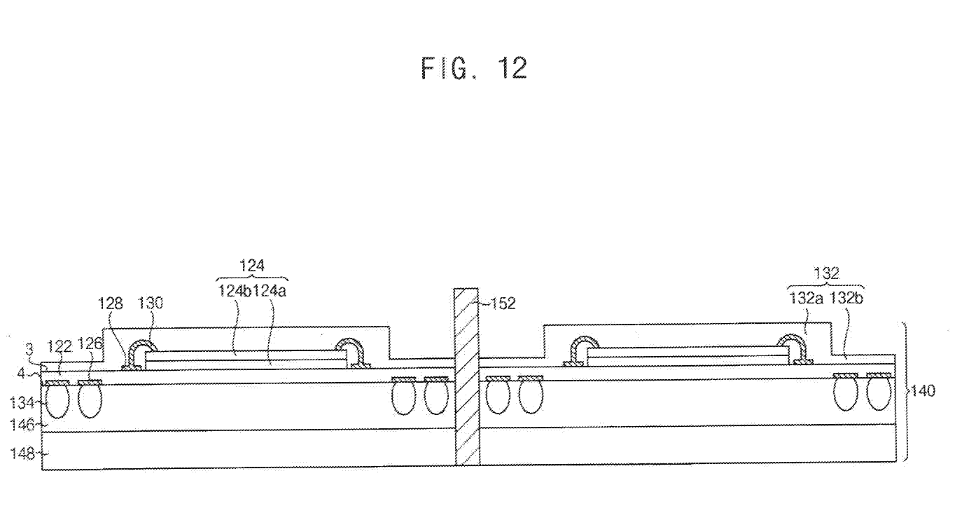

Referring to FIG. 12, the second package substrate 122 is divided, e.g., into two portions, by a second sawing process to obtain second packages 140 each including the second semiconductor chip 124. A second blade 152 is used for performing the second sawing process.

According to an embodiment, the first sawing process and the second sawing process are performed individually.

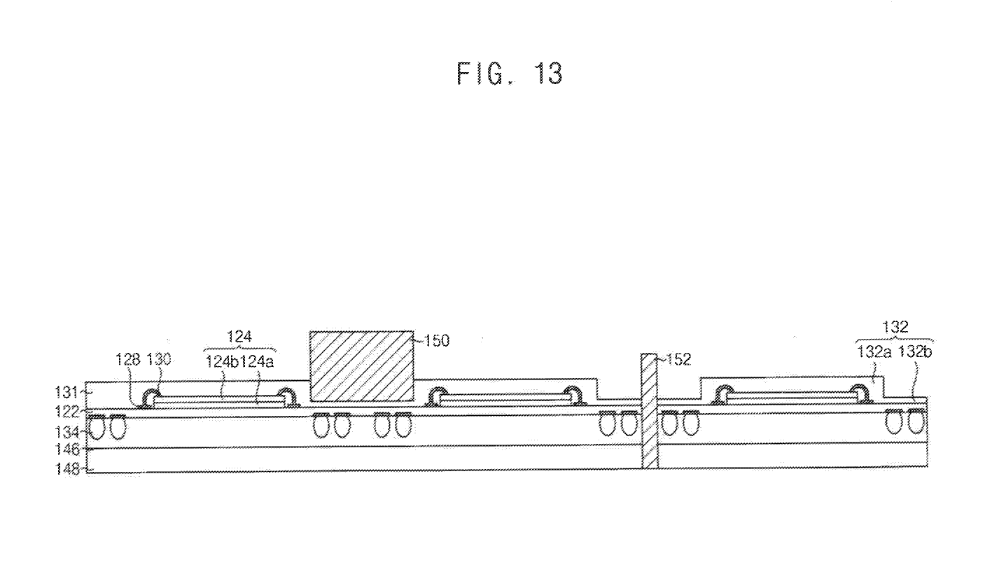

Alternatively, the first and second sawing processes are performed continuously in a single sawing process. As illustrated in FIG. 13, the first blade 150 and the second blade 152 are arranged so that the second sawing process is sequentially performed after performing the first sawing process.

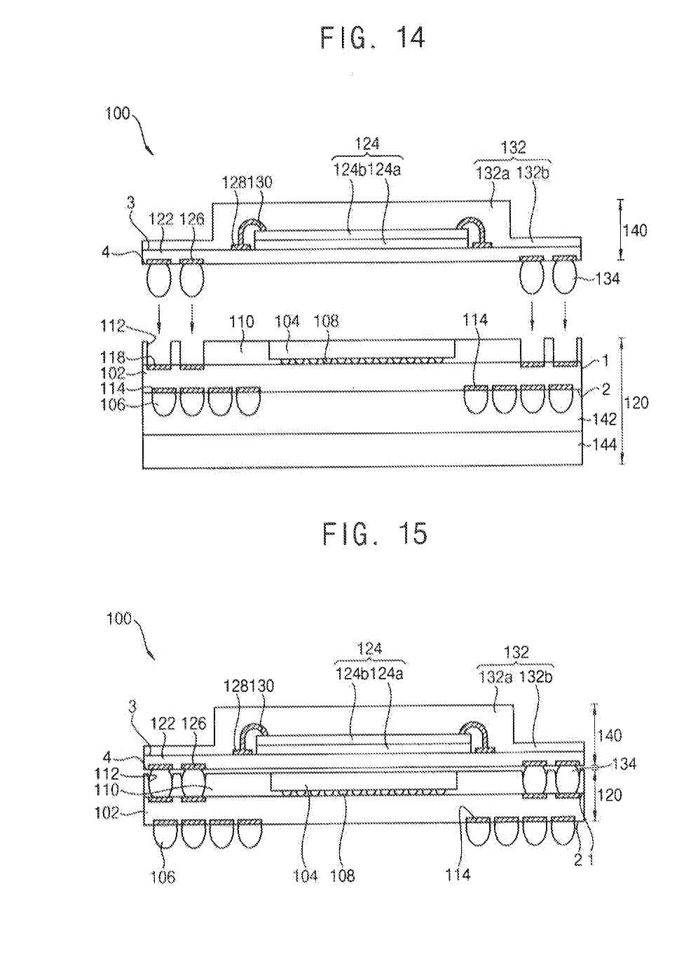

Referring to FIG. 14, the second carrier substrate 148 and the second temporary adhesive 146 are removed such that the second solder balls 134 are exposed. The second solder balls 134 are inserted into the openings 112 formed in the first molding member 110.

Referring to FIG. 15, a reflow process is performed so that the second solder balls 134 contact the first pads 118. Thus, the first pads 118 of the first package 120 and the fourth pads 126 of the second package 140 are electrically connected to each other via the second solder balls 134. The first carrier substrate 144 and the first temporary adhesive 142 are removed such the first solder balls 106 are exposed, thus forming a package stack 100 including the first and second packages 120 and 140.

According to an exemplary embodiment, a portion of the second molding member 132 formed on a peripheral portion of the second package substrate 122 has a relatively thin thickness. A portion of the second molding member 132 formed over the second solder balls 134 has a relatively thin thickness. Therefore, a thermal stress exerted to the second solder balls 134 is reduced so that defects, such as cracks or seams, generated in the second solder halls 134 can be prevented.

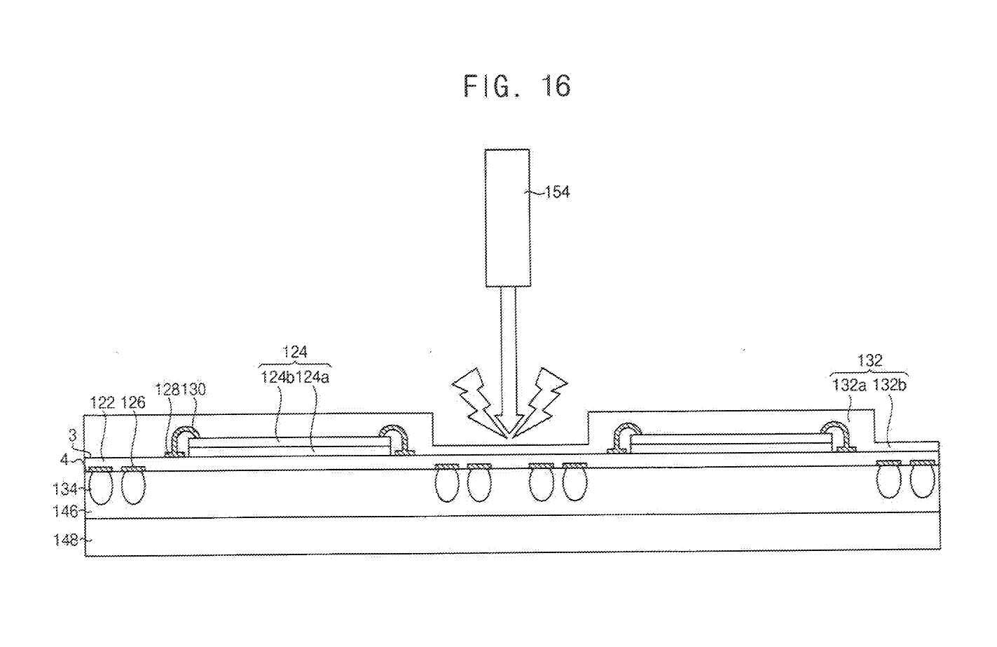

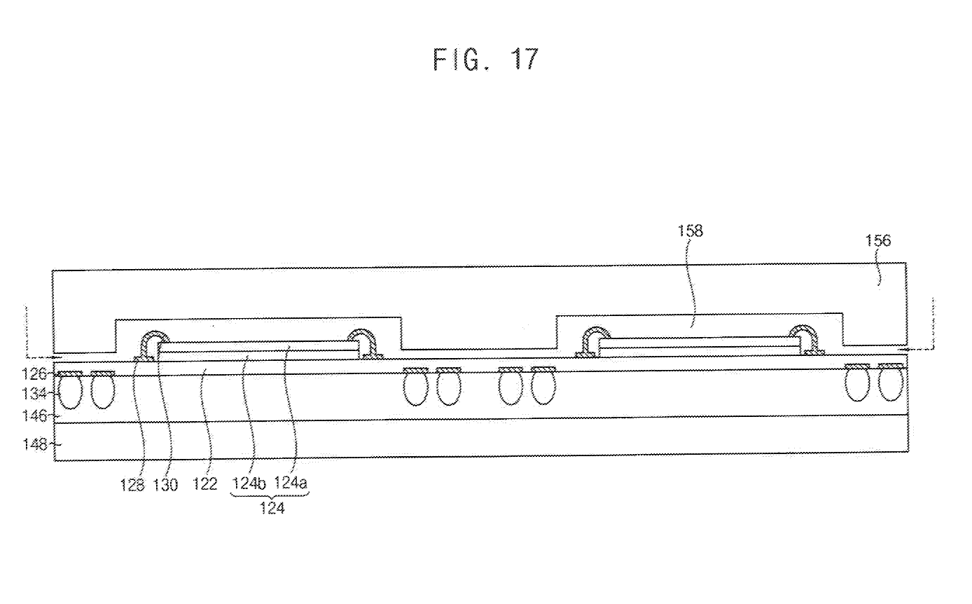

FIG. 16 is a cross-sectional view illustrating a method of manufacturing the package stack of FIG. 1 in accordance with an exemplary embodiment.

The method illustrated in FIG. 16 is the same or substantially the same as the method described with reference to FIGS. 6 to 15 except for a process of forming the second molding member.

Referring to FIG. 16, a portion of the preliminary second molding member overlapping or substantially overlapping or facing the second solder balls 134 is removed to form the second molding member 132. A portion of the preliminary second molding member is removed by a grinding process using a laser 154. The package stack 100 of FIG. 1 is formed by performing processes the same or substantially the same as the processes described with reference to FIGS. 14 and 15.

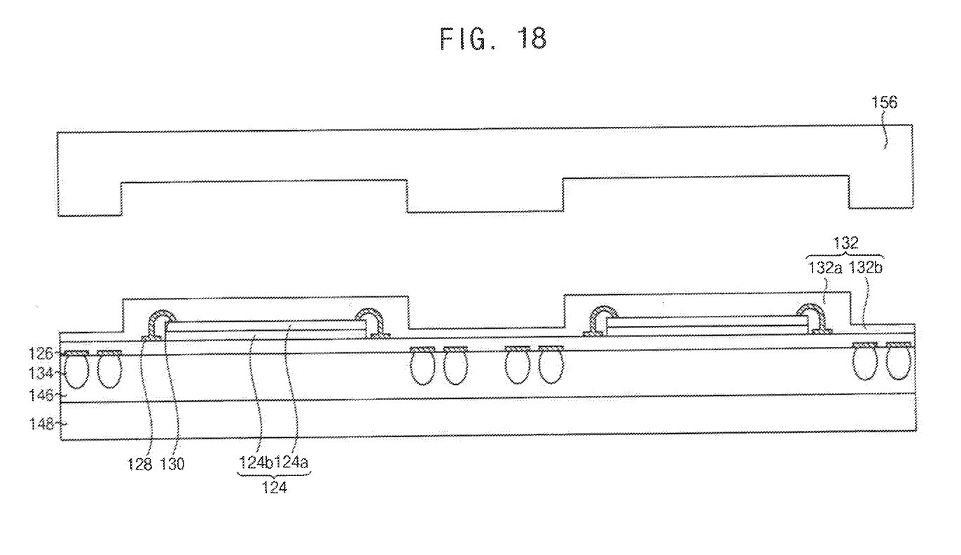

FIGS. 17 and 18 are cross-sectional views illustrating a method of manufacturing the package stack of FIG. 1 in accordance with an exemplary embodiment.

The method described in connection with FIGS. 17 and 18 is the same or substantially the same as the method described with reference to FIGS. 6 to 15 except for a process of forming the second molding member.

The second semiconductor chip 124 and the conductive wires 130 are formed on the second package substrate 122.

Referring to FIG. 17, a mold forming member 156 is disposed over the second surface 2 of the second package substrate 122. A gap 158 for forming the second molding member is defined between the mold forming member 156 and the second package substrate 122.

In an exemplary embodiment, the mold forming member 156 includes recesses overlapping or substantially overlapping or facing the second semiconductor chips 124 and protrusions overlapping or substantially overlapping the second solder balls 134.

Referring to FIG. 18, a mold material is injected through the gap between the mold forming member 156 and the second package substrate 122 to form the second molding member 132. In an exemplary embodiment, the first portion 132a of the second molding member 132 is formed by the recesses of the mold forming member 156, and the second portion 132b of the second molding member 132 is formed by the protrusions of the mold forming member 156. The second molding member 132 is formed according to a profile or a shape of the mold forming member 156, thus eliminating the need of a sawing or grinding process.

The package stack 100 of FIG. 1 is formed by performing processes the same or substantially the same as the processes described with reference to FIGS. 14 and 15.

According to an exemplary embodiment described above, a portion of the second molding member 132 formed on a peripheral portion of the second package substrate 122 has a relatively thin thickness. A portion of the second molding member 132 formed over the second solder balls 134 has a relatively thin thickness. Therefore, a thermal stress exerted to the second solder balls 134 is reduced so that defects, such as cracks or seams, generated in the second solder balls 134 can be prevented.

The package stack according to an exemplary embodiment is employed in various electronic devices or systems.

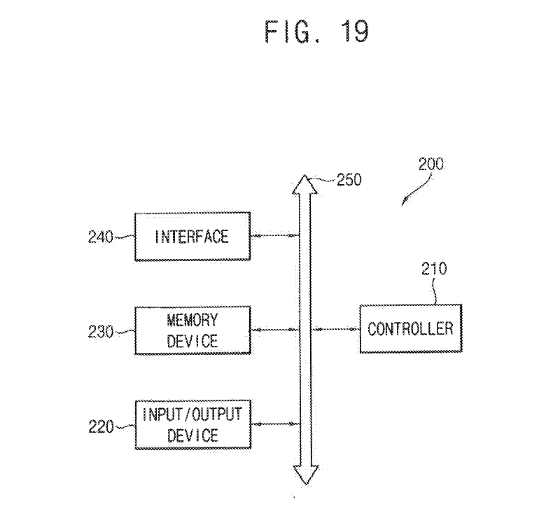

FIG. 19 is a block diagram illustrating an electronic device including a package stack in accordance with an exemplary embodiment.

Referring to FIG. 19, an electronic system 200 includes a controller 210, an input/output device 220 and a memory device 230. The controller 210, the input/output device 220 and the memory device 230 are electrically connected to each other through a bus 250. The bus 250 functions as a path through which data is moved or transmitted. The controller 210 includes at least one of, e.g., a microprocessor, a digital signal processor, a microcontroller and a logic device. The controller 210 and the memory device 230 include a package stack according to an exemplary embodiment. The input/output device 220 includes at least one of a keypad, a keyboard and a display device. Data and/or instructions from the controller 210 are stored in the memory device 230. The memory device 230 includes a volatile memory device or a non-volatile memory device. The electronic system 200 further includes an interface 240 for sending data to a communication network or receiving data from the communication network. The interface 240 has a wired/wireless structure. For example, the interface 240 includes an antenna or a transceiver. The electronic system 200 further includes an application chipset or a camera image processor (CIS).

The foregoing is illustrative of the exemplary embodiments and is not to he construed as limiting thereof. Although a few exemplary embodiments have been described, those skilled in the art will readily appreciate that many modifications are possible in the exemplary embodiments. Accordingly, all such modifications are intended to be included within the scope of the embodiments of the present inventive concept as defined in the claims.

What is claimed is:

1. A method of manufacturing a package stack, the method comprising:
forming a first package, the first package including a first semiconductor chip and connecting pads;
forming a second package, the second package including a second package substrate, a second semiconductor chip on the second package substrate and solder balls on a bottom of the second package substrate;
forming a molding member, the molding member covering an upper surface of the second package substrate and the second semiconductor chip, wherein a portion of the molding member overlapping the solder balls has a thickness smaller than a thickness of another portion of the molding member; and
connecting the solder balls to the connecting pads such that the second semiconductor chip is electrically connected to the first semiconductor chip.

2. The method of claim 1, wherein the solder balls are formed on a bottom of a peripheral portion the second package substrate.

3. The method of claim 1, further comprising:
forming a preliminary molding member covering the second semiconductor chip on the second package substrate; and
removing a portion of the preliminary molding member overlapping the solder balls.

4. The method of claim 1, further comprising:
arranging a mold forming member over the second package, the mold forming member including a protrusion disposed over the solder balls;
injecting a mold material through a gap between the mold forming member and the second package substrate to form the molding member; and
removing the mold forming member.

5. The method of claim 3, wherein the portion of the preliminary molding member is removed by a sawing process utilizing a blade.

6. The method of claim 1, further comprising dividing the second package substrate into a plurality of portions.

7. The method of claim 6, wherein removing the portion of the preliminary molding member and dividing the second package substrate are performed in a single sawing process utilizing two blades.
